(19) United States
(12) Patent Application Publication
(10) Pub. No.: US 2025/0285865 A1
(43) Pub. Date: Sep. 11, 2025

(54) PHOTOMASK FOR SEMICONDUCTOR MANUFACTURING AND METHOD FOR FORMING PHOTOMASK PATTERN

(71) Applicant: Powerchip Semiconductor Manufacturing Corporation, Hsinchu (TW)

(72) Inventors: Jian-Ren Lai, Hsinchu (TW); Pei-Shan Shih, Hsinchu County (TW); Yi-Shiang Chang, Hsinchu City (TW)

(73) Assignee: Powerchip Semiconductor Manufacturing Corporation, Hsinchu (TW)

(21) Appl. No.: 18/611,682

(22) Filed: Mar. 20, 2024

(30) Foreign Application Priority Data
Mar. 7, 2024 (TW) 113108422

(51) Int. Cl. H01L 21/033; G03F 1/36

(52) U.S. Cl. CPC H01L 21/0337; G03F 1/36

(57) ABSTRACT

A photomask for semiconductor manufacturing includes multiple first blocks and multiple second blocks. A line width and a space of the first blocks fall outside a predetermined range, and a combination of the line width and the space of the second blocks in a direction falls within the predetermined ranges. In each of the second blocks, at least one cutting line is included. The cutting line passes through a center point of the each of the second blocks to eliminate the possibility of side lobe formation.

### CROSS-REFERENCE TO RELATED APPLICATION

This application claims the priority benefit of Taiwan application serial no. 113108422, filed on Mar. 7, 2024. The entirety of the above-mentioned patent application is hereby incorporated by reference herein and made a part of this specification.

### BACKGROUND

### Technical Field

This disclosure relates to a photomask design technology, and in particular to a photomask for semiconductor manufacturing that may eliminate side lobe and a method for forming photomask pattern.

### Description of Related Art

In the field of semiconductor manufacturing, in order to form a specific pattern on the substrate (including a variety of device patterns, such as gate, contact), the corresponding pattern is first designed in the computer system, and then the pattern is output to the photomask after optical correction, and then the pattern on the photomask is transferred to form the semiconductor device using the lithography and etching steps.

However, as device dimensions continue to shrink, new lithography equipment and improved processes are being developed. Currently, resolution enhancement technology (RET) can be utilized to improve resolution and drive the lithography process towards advanced nodes. However, RET has been found to be prone to side lobe formation.

### SUMMARY

The disclosure provides a photomask for semiconductor manufacturing, capable of avoiding side lobe formation.

The disclosure also provides a method for forming a photomask pattern, capable of reducing turn around time (TAT) and outputting a side lobe-less photomask pattern.

The photomask for semiconductor manufacturing of the disclosure includes multiple first blocks and multiple second blocks. A line width and a space of the first block fall outside a predetermined range, and a combination of a line width and a space of the second block in a direction fall within the predetermined range. Each of the second blocks includes at least one cutting line. The cutting line passes through a center point of the each of the second blocks.

The method for forming a photomask pattern of the disclosure includes the following. Lithography simulation is performed on multiple regular patterns with different dimensions to obtain a side lobe related table. The side lobe related table shows a simulation result that a side lobe is within a line width range and a space range. According to the side lobe related table, at least one cutting line is added to multiple second blocks in an original photomask pattern that meet the line width range or the space range, in which the cutting line passes through a center point of each of the second blocks. Then, a side lobe-less photomask pattern is output. The side lobe-less photomask pattern includes multiple first blocks falling outside the line width range and the space range in the original photomask pattern and the second blocks added with the cutting line.

In the embodiment of the formation method of the disclosure, optical proximity correction (OPC) may also be used to compensate for lithography errors before adding the cutting line.

In various embodiments of the disclosure, the at least one cutting line may be a single cutting line or a cross-shaped cutting line.

In various embodiments of the disclosure, the cross-shaped cutting line is connected to edges of the each of the second blocks.

In various embodiments of the disclosure, the cross-shaped cutting line is indented from edges of the each of the second blocks.

In various embodiments of the disclosure, the single cutting line is connected to edges of the each of the second blocks.

In various embodiments of the disclosure, both ends of the single cutting line are indented from edges of the each of the second blocks.

Based on the above, the disclosure uses a predetermined side lobe related table to directly add cutting lines to the corresponding lighting patterns that may form side lobe, which may effectively suppress the side lobe problem of lithography and has fewer layout design restrictions, and may reducing turn around time (TAT) compared to the existing OPC reconstruction method.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 is an original photomask pattern and a lithography simulation diagram thereof in a first step of a method for forming a photomask pattern according to a first embodiment of the disclosure.

FIG. 2 is a side lobe related table obtained according to a simulation result in FIG. 1.

FIG. 3 is a side lobe-less photomask pattern and a lithography simulation diagram thereof in a second step according to the first embodiment.

FIG. 4A shows an original photomask pattern of a single block and an improved side lobe-less photomask pattern.

FIG. 4B is an aerial image obtained by the two photomask patterns in FIG. 4A.

FIG. 5A is another improved side lobe-less photomask pattern of a single block.

FIG. 5B is another improved side lobe-less photomask pattern of a single block.

FIG. 5C is another improved side lobe-less photomask pattern of a single block.

FIG. 6 is a flowchart for forming a photomask pattern according to a second embodiment of the disclosure.

FIG. 7A is a schematic diagram of a photomask for semiconductor manufacturing before and after improvement according to a third embodiment of the disclosure.

FIG. 7B is a schematic diagram of another photomask for semiconductor manufacturing before and after improvement according to the third embodiment.

FIG. 8A is a schematic diagram of a photomask for semiconductor manufacturing before and after improvement according to a fourth embodiment of the disclosure.

FIG. 8B is a schematic diagram of another photomask for semiconductor manufacturing before and after improvement according to the fourth embodiment.

### DESCRIPTION OF THE EMBODIMENTS

The following description provides various embodiments for implementing various features of the disclosure. In addition, these embodiments are only exemplary and are not intended to limit the scope and application of the disclosure. Moreover, the relative dimensions (e.g., length, line width, space, etc.) and relative positions of regions or structural components may be reduced or expanded for clarity. Furthermore, similar or identical numeral references used in different drawings represent similar or identical components or features.

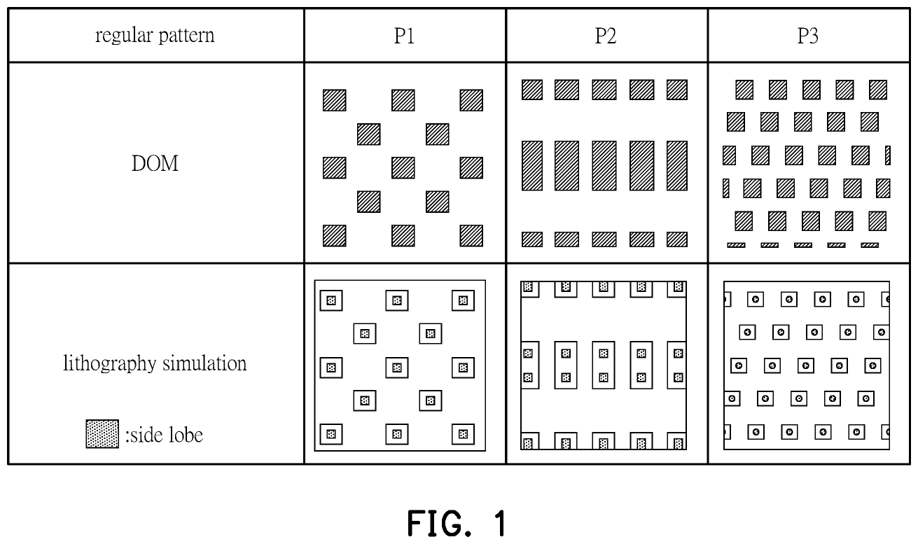

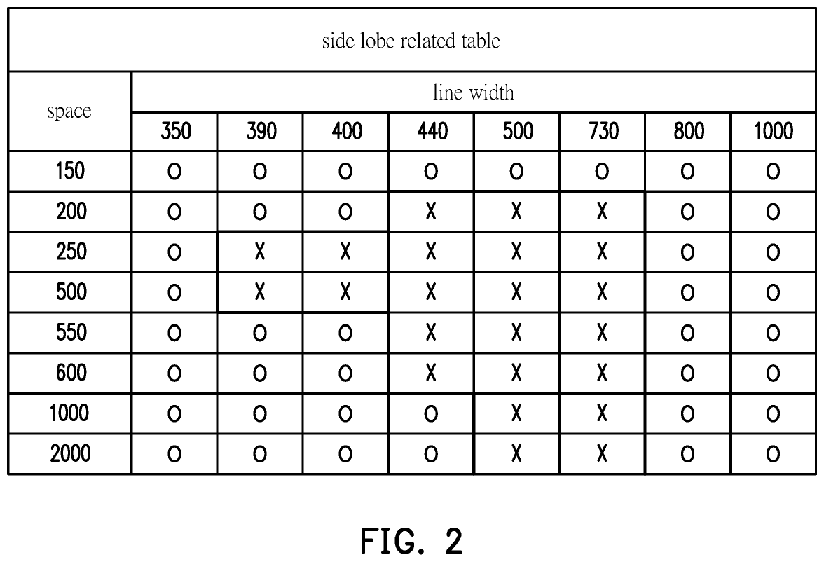

In a method for forming a photomask pattern of a first embodiment of the disclosure, it is necessary to first find out through simulation the dimension range in which side lobe may be formed in various regular patterns with different dimensions, so as shown in FIG. 1, original photomask patterns (also known as DOM (dimension on mask)) of different regular patterns P1, P2, and P3 are pre-designed, and then obtain simulation results by using lithography simulation. For example, the upper row of FIG. 1 shows the DOM, and the simulation results of the lower row all have side lobe, which means that the current line widths or space of the regular patterns P1, P2, and P3 may form side lobe after the lithography process, and so the current dimensions are recorded in a side lobe related table in FIG. 2 and labeled with “X”, and the numerical units in the table are in nanometers. Line widths and spaces of DOM that are simulated by lithography to be free of side lobe are labeled as “O” in the side lobe related table in FIG. 2, and so on. Therefore, from the side lobe related table, it can be obtained that the simulation results within a specific line width range and a specific space range have side lobe, and the patterns outside the above line width range/space range do not have side lobe, so such a range can be defined as a “predetermined range”, in which the dimension of the space in the same direction varies according to the corresponding line width range. This side lobe related table may change due to different parameters of the lithography process. For example, the optical settings of the lithography process (illumination system, phase shift photomask, exposure energy, etc.) will affect the content of the side lobe related table, so the range of values in FIG. 2 is not fixed, but slightly varies according to the different lithography processes.

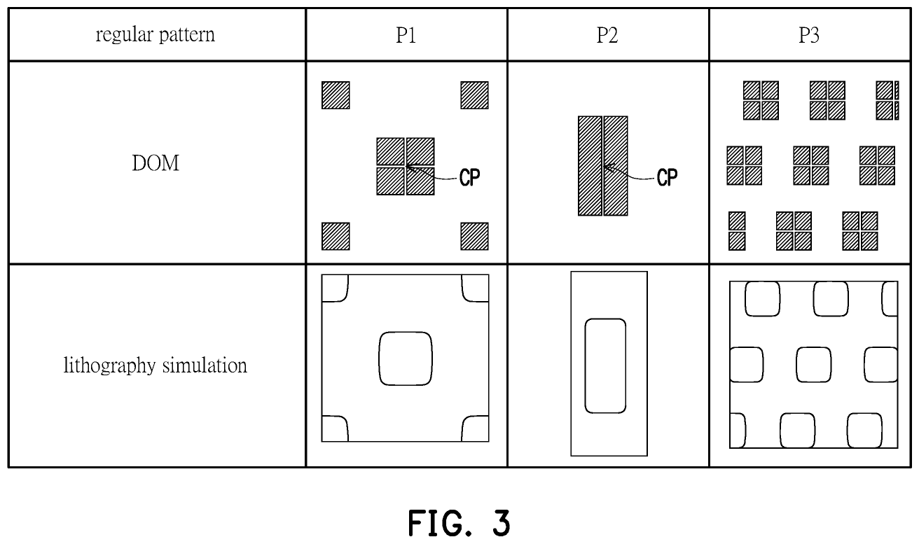

In the method for forming a photomask pattern of the first embodiment, after obtaining the side lobe related table in FIG. 2, pattern side-lobe cutting (PSC) can be performed according to the dimension of “X” labeled therein. For example, a partially enlarged view of the DOM in the upper row of FIG. 1 is placed on the upper row of FIG. 3, and at least one cutting line is added to the blocks in the regular patterns P1, P2, and P3, and each cutting line passes through the center point CP of the block. The cutting lines in the regular patterns P1 and P3 are cross-shaped cutting lines, and the cutting line in the regular pattern P2 is single cutting line. The results of lithography simulation of the DOMs with cutting lines do not have side lobe.

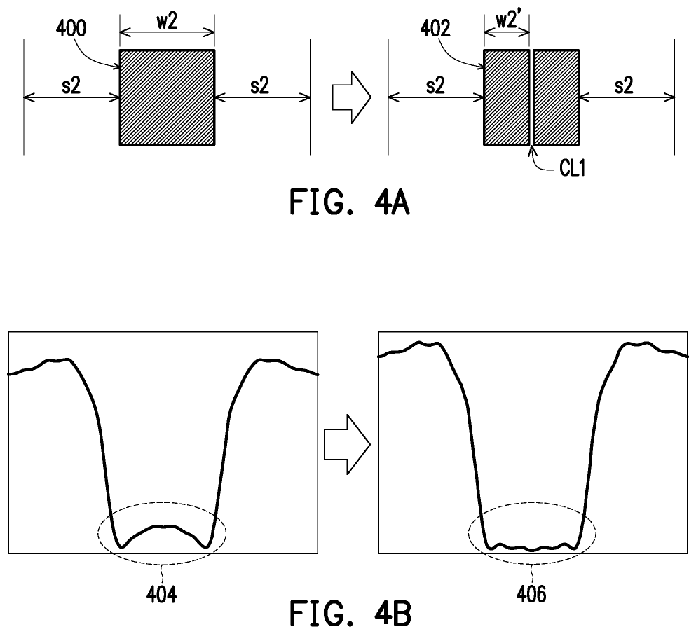

In order to further confirm the above effects, please refer to FIG. 4A and FIG. 4B. FIG. 4A shows an original photomask pattern of a single block and an improved side lobe-less photomask pattern. FIG. 4B is an aerial image obtained by the two photomask patterns in FIG. 4A.

In FIG. 4A, if a combination of a line width w2 and a space s2 of a single block 400 meets the dimension “X” labeled in the side lobe related table of FIG. 2, then after improvement (i.e., PSC), a cutting line CL1 is added to a block 402, and the cutting line CL1 is connected to the edge of the block 402, so that a line width w2′ of the block 402 is greatly reduced and a combination of the w2′ and s2 meets the dimension “O” labeled in the in the side lobe related table of FIG. 2. Moreover, although FIG. 4A only shows the line width w2 and the space s2 in the horizontal direction (X-axis), it should be known that the dimensions in the vertical direction (Y-axis) should also follow the side lobe related table to decide whether or not to add the cutting line in the block 400.

In FIG. 4B, the picture on the left is an aerial image of the photoresist obtained by exposing and developing the photomask with the block 400, and the picture on the right is an aerial image of the photoresist obtained by exposing and developing the photomask with the block 402.

The result is that the unimproved original photomask pattern has a higher distribution of light intensity in a center 404 of the tangent of the pattern, which means that it is prone to side lobe formation. In contrast, the improved side lobe-less photomask pattern maintains a similar distribution of light intensity in a center 406 of the tangent of the pattern, so it can be deduced that there is no side lobe formation here.

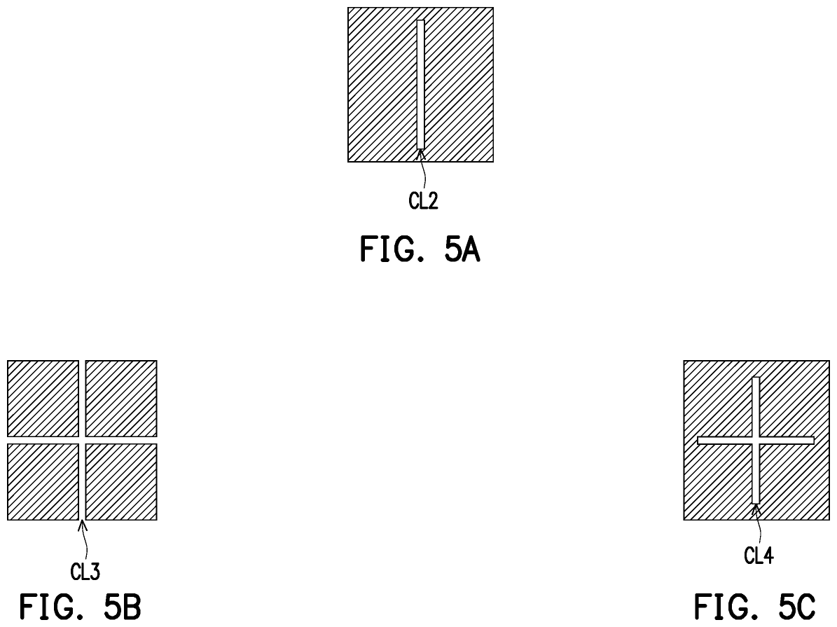

In addition to the cutting line CL1 in FIG. 4A, the types of the cutting line in FIG. 5A, FIG. 5B, or FIG. 5C may also be used.

In FIG. 5A, A cutting line CL2 is a single cutting line, and its two ends are indented from the edges of the block.

In FIG. 5B, a cutting line CL3 is a cross-shaped cutting line and is connected to the edges of the block.

In FIG. 5C, a cutting line CL4 is a cross-shaped cutting line, and the cutting line CL4 is indented from the edges of the block.

The above cutting lines CL1, CL2, CL3 and CL4 may be used in different blocks in the same photomask, or one or more of the cutting lines may be used in the same photomask to improve the photomask pattern with side lobe formation. The dimension of the cutting line or its indentation may be adjusted according to the specifications of the photomask writing.

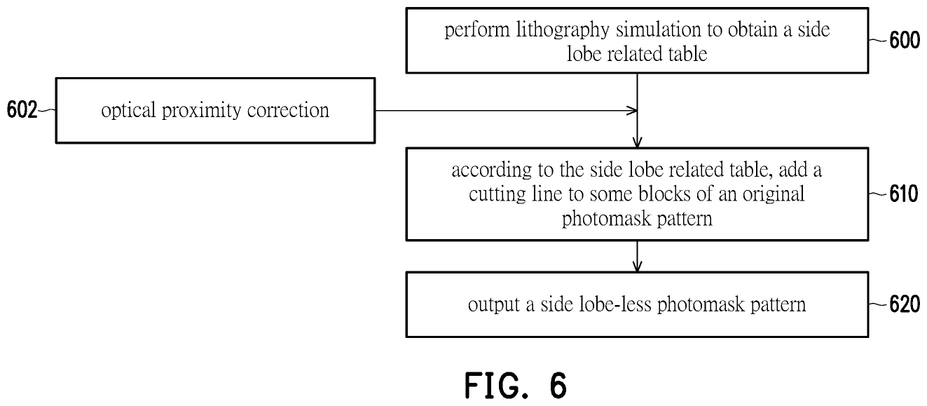

FIG. 6 is a flowchart for forming a photomask pattern according to a second embodiment of the disclosure.

Referring to FIG. 6, first, in step 600, lithography simulation is performed on multiple regular patterns with different dimensions to obtain a side lobe related table, which shows a simulation result that there is side lobe within a line width range and a space range. The details of step 600 can be referred to FIG. 1 and FIG. 2 and will not be repeated in the following.

In step 610, according to the side lobe related table obtained in step 600, at least one cutting line is added to multiple second blocks in an original photomask pattern that meet the combination of the line width range and the space range. The cutting line passes through a center point of each second block, as shown in FIG. 4A, FIG. 5A, FIG. 5B, or FIG. 5C. In addition, before step 610, optical proximity correction (OPC) can be used to compensate for lithography errors (step 602). Thus, the method of the second embodiment is not limited to OPC processing and may complete the photomask pattern more efficiently.

In step 620, a side lobe-less photomask pattern is output, which includes multiple first blocks falling outside the line width range and space range in the original photomask pattern, as well as multiple second blocks with added cutting lines.

Two embodiments are listed below, which are photomask for semiconductor manufacturing output according to the method for forming a photomask pattern.

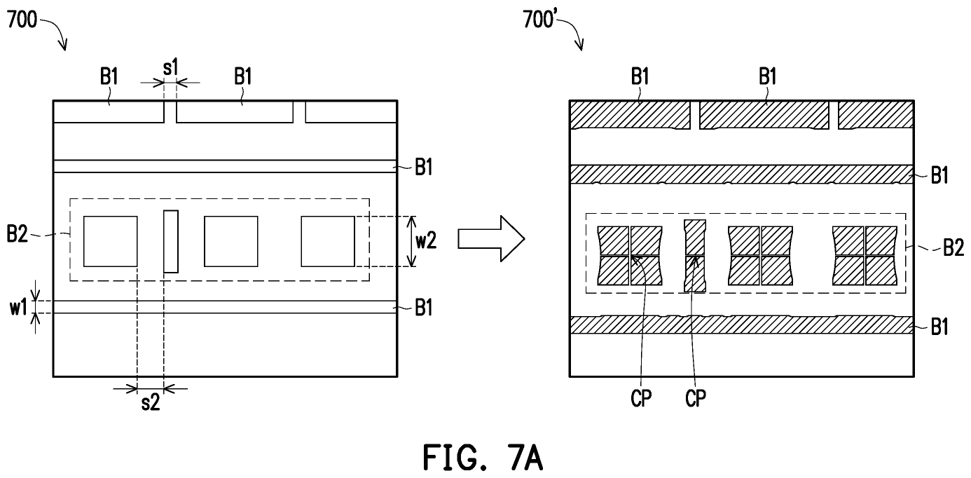

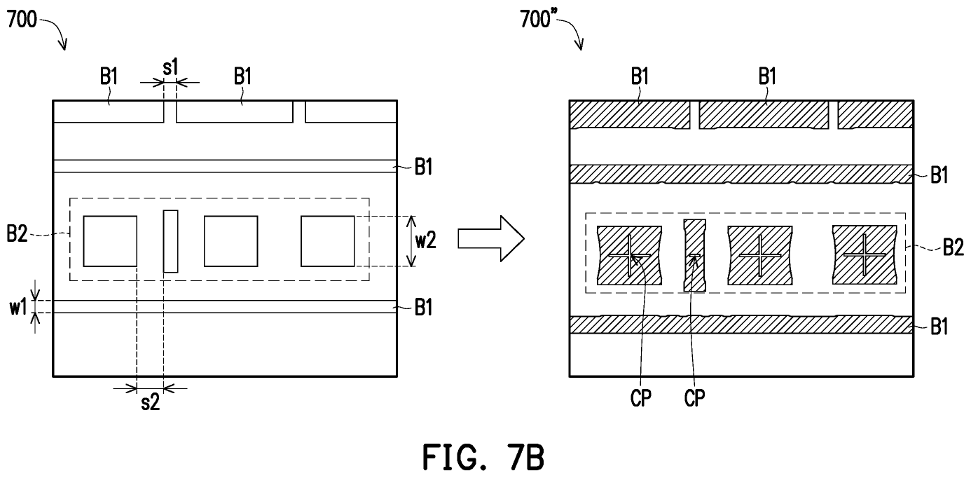

FIG. 7A is a schematic diagram of a photomask for semiconductor manufacturing before and after improvement according to a third embodiment of the disclosure.

Referring to FIG. 7A, an original photomask pattern 700 is shown on the left, which includes multiple first blocks B1 and multiple second blocks B2, and the second block B2 is surrounded by dashed lines. A line width w1 and a space s1 of the first block B1 fall outside a predetermined range, and the combination of the line width w2 and the space s2 of the second block B2 fall within the predetermined range. By improving the steps in FIG. 6, a side lobe-less photomask pattern 700′ on the right can be obtained as a photomask for semiconductor manufacturing, and includes at least one cutting line in each second block B2, the cutting line passing through the center point CP of the each second block B2.

FIG. 7B is a schematic diagram of another photomask for semiconductor manufacturing before and after improvement according to the third embodiment. The original photomask pattern 700 is also shown on the left, and the cutting lines in a side lobe-less photomask pattern 700″ on the right are all indented from the edges of the second block B2.

After lithography simulation, the CD bias of the side lobe-less photomask pattern 700′ in FIG. 7A is about 2.6%, and the CD bias of the side lobe-less photomask pattern 700″ in FIG. 7B is about 0.5%.

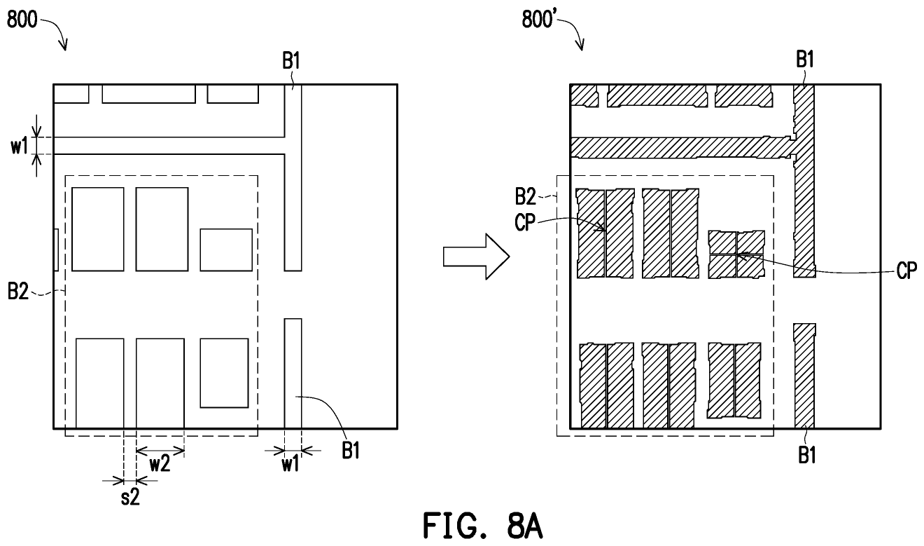

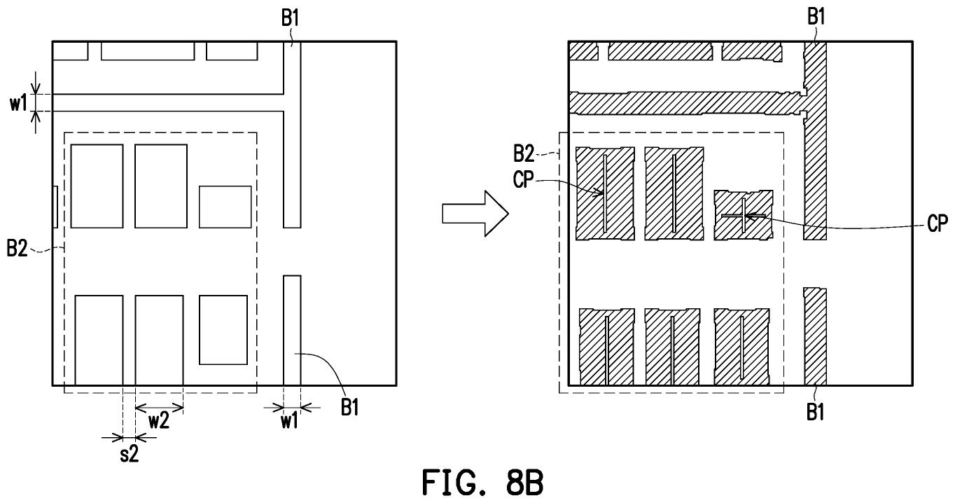

FIG. 8A is a schematic diagram of a photomask for semiconductor manufacturing before and after improvement according to a fourth embodiment of the disclosure.

Referring to FIG. 8A, another original photomask pattern 800 is shown on the left, which includes multiple first blocks B1 and multiple second blocks B2, and the second block B2 is surrounded by dashed lines. A line width w1 of the first block B1 falls outside the predetermined range, and a line width w2 or a space s2 of the second block B2 falls within the predetermined range. By improving the steps in FIG. 6, a side lobe-less photomask pattern 800′ on the right can be obtained as a photomask for semiconductor manufacturing, and includes at least one cutting line in each second block B2, the cutting line passing through the center point CP of the each second block B2. In addition, due to the optical proximity correction (OPC) process, the edges of the first block B1 and the second block B2 in the side lobe-less photomask pattern 800′ are obviously not straight lines.

FIG. 8B is a schematic diagram of another photomask for semiconductor manufacturing before and after improvement according to the fourth embodiment. The original photomask pattern is also shown on the left, and the cutting lines in the side lobe-less photomask pattern on the right are all indented from the edges of the second block B2.

Based on the above, whether it is a regular pattern or an original photomask pattern with complex and different dimensions, the formation method of the disclosure may directly and simply improve the photomask pattern, effectively suppressing the side lobe problem of lithography and reducing turn around time (TAT) compared to the existing OPC reconstruction method.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A photomask for semiconductor manufacturing, comprising:
a plurality of first blocks, wherein a line width and a space of the first blocks fall outside a predetermined range; and
a plurality of second blocks, wherein a combination of a line width and a space of the second blocks in a direction fall within the predetermined range, and each of the second blocks comprises at least one cutting line, wherein the at least one cutting line passes through a center point of the each of the second blocks.

2. The photomask for semiconductor manufacturing according to claim 1, wherein the at least one cutting line is a single cutting line or a cross-shaped cutting line.

3. The photomask for semiconductor manufacturing according to claim 2, wherein the cross-shaped cutting line is connected to edges of the each of the second blocks.

4. The photomask for semiconductor manufacturing according to claim 2, wherein the cross-shaped cutting line is indented from edges of the each of the second blocks.

5. The photomask for semiconductor manufacturing according to claim 2, wherein the single cutting line is connected to edges of the each of the second blocks.

6. The photomask for semiconductor manufacturing according to claim 2, wherein both ends of the single cutting line are indented from edges of the each of the second blocks.

7. A method for forming a photomask pattern, comprising:
performing lithography simulation on a plurality of regular patterns with different dimensions to obtain a side lobe related table, wherein a simulation result shows that a side lobe is within a line width range and a space range;
according to the side lobe related table, adding at least one cutting line to a plurality of second blocks in an original photomask pattern that meet the line width range or the space range, wherein the at least one cutting line passes through a center point of each of the second blocks; and
outputting a side lobe-less photomask pattern, wherein the side lobe-less photomask pattern comprises a plurality of first blocks falling outside the line width range and the space range in the original photomask pattern and the second blocks added with the at least one cutting line.

8. The method for forming a photomask pattern according to claim 7, wherein the at least one cutting line is a single cutting line or a cross-shaped cutting line.

9. The method for forming a photomask pattern according to claim 8, wherein the cross-shaped cutting line is connected to edges of the each of the second blocks.

10. The method for forming a photomask pattern according to claim 8, wherein the cross-shaped cutting line is indented from edges of the each of the second blocks.

11. The method for forming a photomask pattern according to claim 8, wherein the single cutting line is connected to edges of the each of the second blocks.

12. The method for forming a photomask pattern according to claim 8, wherein both ends of the single cutting line are indented from edges of the each of the second blocks.

13. The method for forming a photomask pattern according to claim 7, further comprising using optical proximity correction (OPC) to compensate for lithography errors before adding the at least one cutting line.
